(19) United States
(12) Patent Application Publication
(10) Pub. No.: US 2026/0157010 A1
(43) Pub. Date: Jun. 4, 2026

(54) DISPLAY APPARATUS

(71) Applicant: LG Display Co., Ltd., Seoul (KR)

(72) Inventors: Jae-Kyung SHIN, Paju-si (KR); Joon-Kwon MOON, Paju-si (KR); Jae-Hoon JANG, Paju-si (KR)

(73) Assignee: LG Display Co., Ltd., Seoul (KR)

(21) Appl. No.: 19/183,519

(22) Filed: Apr. 18, 2025

(30) Foreign Application Priority Data
Dec. 2, 2024 (KR) 10-2024-0176311

(51) Int. Cl. H10H 29/856; H10H 29/01; H10H 29/855

(52) U.S. Cl. CPC H10H 29/856; H10H 29/012; H10H 29/0363; H10H 29/8552

(57) ABSTRACT

In one or more examples, a display apparatus includes an insulating layer including a plurality of holes disposed on a substrate and a light-emitting component with a plurality of micro light-emitting diode chips disposed within the plurality of holes. The display apparatus can implement beneficial luminous efficiency and large-area process.

### CROSS-REFERENCE TO RELATED APPLICATIONS

This application claims the benefit of and priority to Korean Patent Application No. 10-2024-0176311, filed in the Republic of Korea on Dec. 2, 2024, the entire contents of which are expressly incorporated herein by reference for all purposes.

### BACKGROUND

### 1. Technical Field

The present disclosure relates to a display apparatus, and more particularly to, for example, without limitation, a display apparatus with a precise location of a light-emitting element.

### 2. Discussion of Related Art

A display apparatus has been applied to various electron devices such as TV, a mobile device, a note book and a tablet PC. The display apparatus comprises a light-emitting display apparatuses such as an organic light-emitting diode (OLED) displays that emit light on their own, and a liquid crystal displays (LCDs) that require a separate light source.

Currently, a display apparatus including a light-emitting diode (LED) has been attracted as a next generation display apparatus. The LED comprises inorganic materials instead of organic materials so that the display apparatus including the LED has advantages of rapid lightning speed, beneficial luminous efficiency and high brightness compared to the OLED display.

The description of the related art should not be assumed to be prior art merely because it is mentioned in or associated with this section. The description of the related art includes information that describes one or more aspects of the subject technology, and the description in this section does not limit the invention.

### SUMMARY

Accordingly, some embodiments of the present disclosure are directed to a display apparatus and a process of fabricating a display apparatus that substantially obviates one or more of the problems due to the limitations and disadvantages of the related art.

An aspect of the present disclosure is to provide a display apparatus with beneficial precision when a light-emitting diode is transferred to a panel.

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims hereof as well as the appended drawings.

To achieve these and other aspects of the inventive concepts, as embodied and broadly described, in one aspect, the present disclosure provides a display apparatus that comprises a substrate; a first electrode disposed on the substrate; a thin film transistor disposed on the substrate and electrically connected to the first electrode; a planarization layer disposed on the thin film transistor; an insulating layer disposed on the planarization and comprising a plurality of holes; and a light-emitting component disposed within the plurality of holes.

In one embodiment, the light-emitting component can comprise a plurality of micro light-emitting diode chips; a plurality of molds surrounding each of the micro light-emitting diode chips, respectively; a reflection wall positioned on at least one outer side of each of the molds; a conductive layer disposed under each of the micro light-emitting diode chips; and a second electrode disposed on the micro light-emitting diode chips, wherein the micro light-emitting diode chips can be electrically connected to the conductive layer and the second electrode.

In one embodiment, the display apparatus can further comprise a photoresist layer surrounding sides of the micro light-emitting diode chips, and wherein the photoresist layer can be positioned to expose an upper end of the micro light-emitting diode chips.

In another embodiment, each of the molds can comprise an inclined surface configured to diffuse light generated from each of the micro light-emitting diode chips.

In another embodiment, each of the molds can have a height equal to or higher than a height of each of the micro light-emitting diode chips.

In another embodiment, each of the micro light-emitting diode chips can be a vertical chip.

In one embodiment, the light-emitting component can further comprise a repair portion.

In another embodiment, the light-emitting component can further comprise a redundancy portion.

The display apparatus can further comprise an adhesive member positioned under the light-emitting component, and the light-emitting component can be electrically connected to the first electrode through the adhesive member.

As an example, the adhesive member can comprise a conductive material.

The adhesive member can comprise a conductive ball.

The display apparatus can further comprise a filling material between the light-emitting component and the planarization layer.

The display apparatus can further comprise a black matrix disposed on the second electrode, and the black matrix can be positioned to expose an upper end of the micro light-emitting diode chips.

In another aspect, the present disclosure provides a process of fabricating a display apparatus, the process comprises preparing a base substrate; disposing an adhesive layer on the entire base substrate; disposing a plurality of molds on the adhesive layer so that recesses are positioned between two of the plurality of the molds; disposing a reflective wall surrounding an outer wall of each of the plurality of the molds; treating thermally the conductive layer to position the conductive layer within each of the recess between two of the plurality of the molds; transferring a plurality of micro light-emitting diode chips on the conductive layer; and curing the conductive layer.

The process can further comprise disposing a photoresist layer on the plurality of the micro light-emitting diode chips.

For Example, disposing the photoresist layer can comprise coating a photoresist-forming composition on the plurality of the micro light-emitting diode chips and performing a photolithography process for the photoresist-forming composition.

In one embodiment, the process can further comprise isolating the plurality of the micro light-emitting diode chips transferred on the conductive layer from the adhesive layer using a stamp, and arranging the plurality of the micro light-emitting diode chips transferred to the conductive layer onto a panel.

As an example, an insulating layer including a plurality of holes can be disposed on the panel, and the plurality of the micro light-emitting diode chips transferred on the conductive layer can be positioned within the plurality of holes.

The process can further comprise depositing a second electrode on the entire photoresist layer.

The process can further comprise disposing a black matrix on the second electrode.

In one or more embodiments, the light-emitting component including the micro light-emitting diode chips are transferred to the panel. A high-resolution display apparatus having an ultra-small micro light-emitting diode chip with improved transfer precision can be fabricated. The light-emitting component can comprise the molds surrounding each micro light-emitting diode chip and a reflection wall disposed on the outer side of the mold so that the display apparatus can increase its luminous efficiency. In addition, the mold can comprise an inclined surface configured to diffuse light generated from the micro light-emitting diode chip so that the display apparatus can maximize its light extraction efficiency.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 illustrates a plane view of a display apparatus in accordance with an embodiment of the present disclosure.

FIG. 2 illustrates a functional block diagram of a display apparatus in accordance with an embodiment of the present disclosure.

FIG. 3 illustrates a schematic circuit diagram of a pixel circuit included in the display apparatus in accordance with an embodiment of the present disclosure.

FIG. 4 illustrates a schematic cross-sectional view of a micro light-emitting diode in accordance with an embodiment of the present disclosure.

FIG. 5 illustrates a light-emitting component deposited on a base substrate in accordance with an embodiment of the present disclosure.

FIGS. 6A and 6B illustrate a fabrication process of a display apparatus in accordance with an embodiment of the present disclosure.

FIG. 7 illustrates a cross-sectional view of a display apparatus in accordance with an embodiment of the present disclosure.

FIGS. 8A and 8B illustrate a plane view of an area A as a light-emitting component in FIG. 7 in accordance with an embodiment of the present disclosure.

FIG. 9 illustrates an enlarged cross-sectional view of an area B in FIG. 7.

FIG. 10 illustrates a cross-sectional view of a display apparatus in accordance with another embodiment of the present disclosure.

FIG. 11 illustrates an enlarged cross-sectional view of an area B′ in FIG. 10.

FIG. 12 illustrates a cross-sectional view of a display apparatus in accordance with an embodiment of the present disclosure.

FIGS. 13 to 16 illustrate devices including the display apparatus in accordance with embodiments of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing embodiments of the present disclosure are merely illustrative examples, and thus the present disclosure is not limited to the illustrated examples. The same reference numerals refer to the same components throughout this disclosure unless otherwise specified. Further, in the following description of the present disclosure, where a detailed description of a known related art may unnecessarily obscure the gist of the present disclosure, the detailed description thereof may be omitted herein or may be briefly discussed.

Where terms such as “including,” “having,” “comprising,” and the like are used in this disclosure, other parts can be added unless a more limiting term like “only” is used herein. Further, where a component is expressed as being singular, being plural is included, and vice versa, unless otherwise specified. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In analyzing or construing a component, an error range should be interpreted as being included even where there is no explicit description.

In describing a positional relationship, for example, where a positional relationship of two parts/layers is described as being “over,” “on,” “above,” “below,” “under,” “next to,” or the like, one or more other parts/layers can be provided between the two parts/layers, unless a more limiting term like “immediately” or “directly” is used therewith.

When a component or layer is referred to as being “on” another component or layer, it includes both instances where the other component is directly on the other component or layer, or where there is another layer or component intervening therebetween.

In describing a temporal relationship, for example, where a temporal predecessor relationship is described as being “after,” “subsequent,” “next to,” “prior to,” or the like, unless a more limiting term like “immediately” or “directly” is used, cases that are not continuous or sequential can also be included.

Although the terms first, second, and the like may be used to describe various components, these components are not substantially limited by these terms. These terms are used only to refer to one component separately from another component, and may not define any particular order or sequence. Therefore, a first component described below can substantially be a second component, and vice versa, within the technical spirit of the present disclosure.

In describing components of this specification, terms such as first, second, A, B, (a), or (b) may be used. These terms are only intended to distinguish the components from other components, and the nature, order, sequence, or numbers of components are not limited by the terms.

When a component is described as being “connected,” “coupled,” “connected,” or “attached,” to another component, it should be understood that the component may be directly connected, coupled, connected, or attached to the other component, but that other components may be interposed between each component that may be indirectly connected, coupled, connected, or attached without specifically expressly stating so.

When a component or layer is described as being “contacted,” or “overlapping,” it should be understood that the component or layer may directly contact or overlap the other component or layer, but that other components may be interposed between each component that may be indirectly contacted or overlapped without specifically expressly stating so. “At least one” should be understood to include any combination of one or more of the associated components. For example, “at least one of the first, second, and third components” can be understood to include not only the first, second, or third components, but also any combination of two or more of the first, second, and third components.

“First direction,” “Second direction,” “Third direction,” “X-axis direction,” “Y-axis direction,” and “Z-axis direction” should not be interpreted as merely geometric relationships in which the relationships between each other are perpendicular, but can mean a wider directionality within the scope in which the configuration of this specification can function functionally.

Features of various embodiments of the present disclosure can be partially or entirely united or combined with each other, technically various interlocking and driving are possible, and each of the embodiments can be independently implemented with respect to each other or implemented together in a co-dependent relationship.

All the components of each display device according to all embodiments of the present disclosure are operatively coupled and configured.

Reference will now be made in detail to aspects of the disclosure, examples of which are illustrated in the accompanying drawings. Wherever possible, the same reference numbers will be used throughout the drawings to refer to the same or like parts.

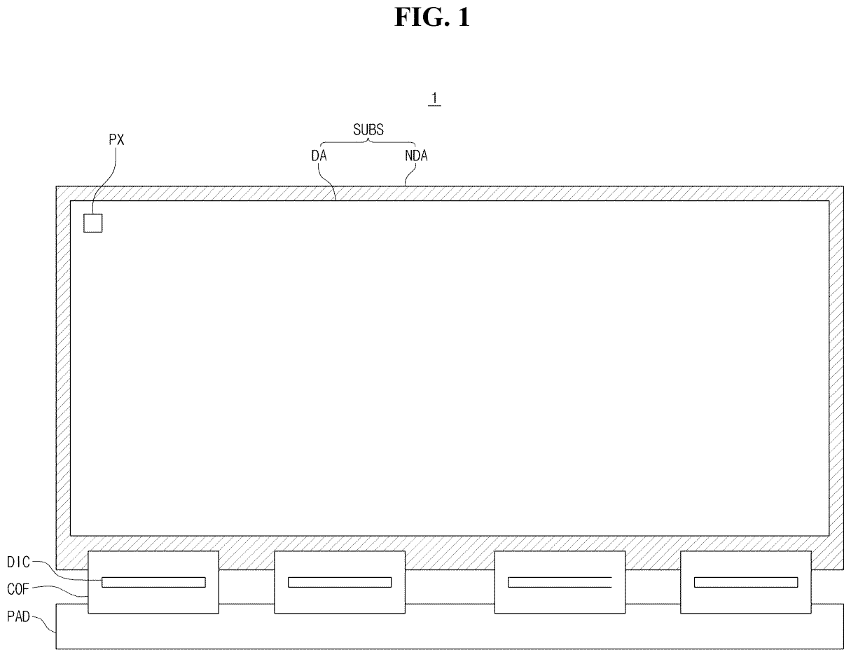

FIG. 1 illustrates a plane view of a display apparatus in accordance with an embodiment of the present disclosure.

As illustrated in FIG. 1, a display apparatus 1 comprises a substrate SUBS including a display area DA and a non-display area NDA. The substrate SUBS can comprise glass and/or plastic. When the substrate SUB is made of plastic, the substrate SUBS can be a flexible substrate. The flexible substrate can be made of a flexible resin and can comprise the same or different materials.

The display area DA can be configured to position on the substrate SUBS and the non-display area NDA can be positioned outside of the display area DA. The non-display area NDA can comprise a pad portion PAD at one side thereof. For example, the pad portion PAD can be positioned, but is not limited to, at lower side of the non-display area NDA. The COF film COF can be provided on the pad portion PAD. The COF film COF can include a driver integrated circuit DIC.

The display area DA can comprise a plurality of pixels PX. In one embodiment, the pixel PX can emit red color light, green color light and a blue color light. Alternatively, the pixel PX can emit red color light, green color light, blue color light and white color light. The display area DA can comprise a GIP driver for applying a gate driving signal to the display area DA at one side thereof. A Chip on Film (COF) can be attached to the pad portion PAD provided on one side of the display area DA. A data signal and a power can be applied to plural signal lines provided in the display area DA through the COF.

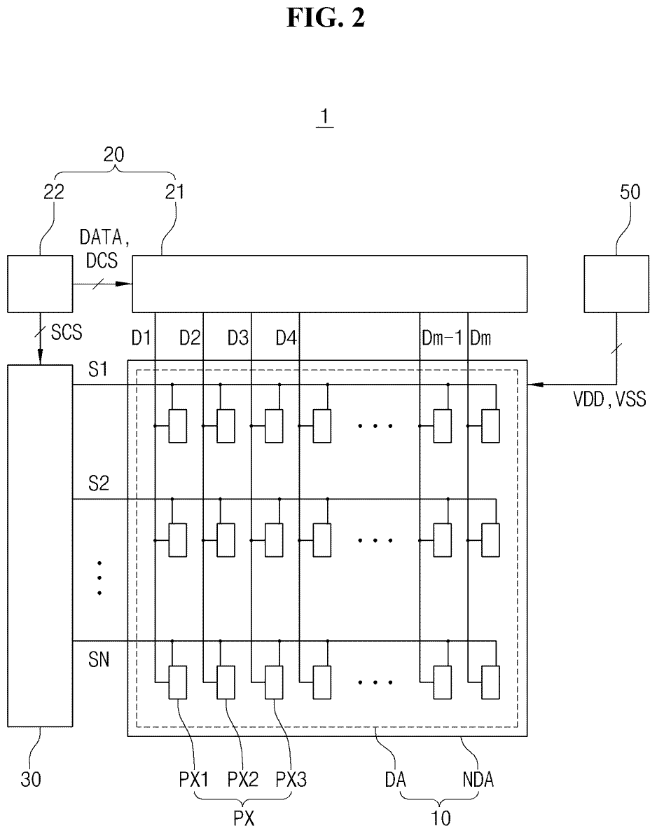

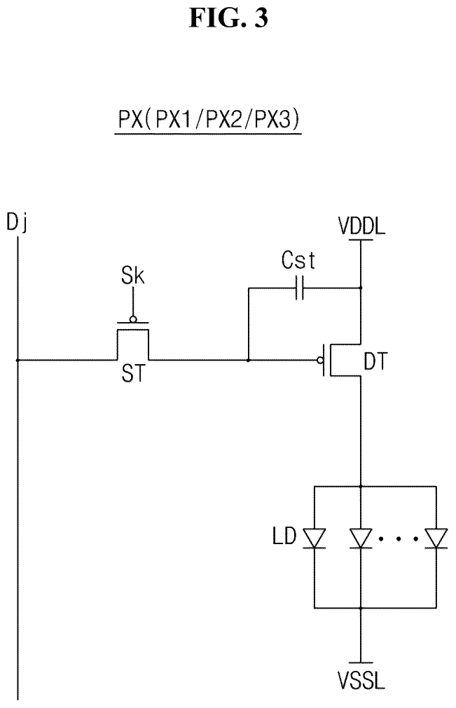

FIG. 2 illustrates a functional block diagram of a display apparatus in accordance with an embodiment of the present disclosure. FIG. 3 illustrates a schematic circuit diagram of a pixel circuit included in the display apparatus in accordance with an embodiment of the present disclosure.

As illustrated in FIGS. 2 and 3, the display apparatus 1 in accordance with an embodiment can comprise a display panel 10, a driving circuit 20, a scan driver 30 and a power supply circuit 50.

The driving circuit can comprise a data driver 21 and a timing controller 22.

As described above, the display area DA in the display panel 10 can be an area where pixels PX are formed to display an image. The display panel 10 can comprise data lines D1 to Dm (wherein m is an integer equal to or greater than 2), scan lines S1 to Sn (wherein n is an integer equal to or greater than 2) crossing the data lines D1 to Dm, a high-potential line to which a high-potential voltage is supplied, a low-potential line to which a low-potential voltage is supplied, and pixels PX connected to the data lines D1 to Dm and the scan lines S1 to Sn.

In one embodiment, each of the pixels PXs can comprise a first sub-pixel PX1, a second sub-pixel PX2 and a third sub-pixel PX3. The first sub-pixel PX1 can emit a first color light with a first wavelength, the second sub-pixel PX2 can emit a second color light with a second wavelength and the third sub-pixel PX3 can emit a third color light with a third wavelength. As an example, the first color light can be a red color light, the second color light can be a green color and the third color light can be a blue color light, but is not limited thereto. In FIG. 2, each pixel PX comprises three sub-pixels, but is not limited thereto. In other words, each of the pixels PXs can comprise four or more sub-pixels.

Each of the first sub-pixel PX1, the second sub-pixel PX2 and the third sub-pixel PX3 can be connected to one of the data lines D1 to Dm, one of the scan lines S1 to Sn and the high-potential voltage line. As illustrated in FIG. 3, each of the first sub-pixel PX1, the second sub-pixel PX2 and the third sub-pixel PX3 can comprise a plurality of light-emitting diodes LDs, a plurality of transistors for supplying current to the light-emitting diodes LDs and at least one capacitor Cst. Alternatively, each of the first sub-pixel PX1, the second sub-pixel PX2 and the third sub-pixel PX3 can comprise one light-emitting diode LD and at least one capacitor Cst.

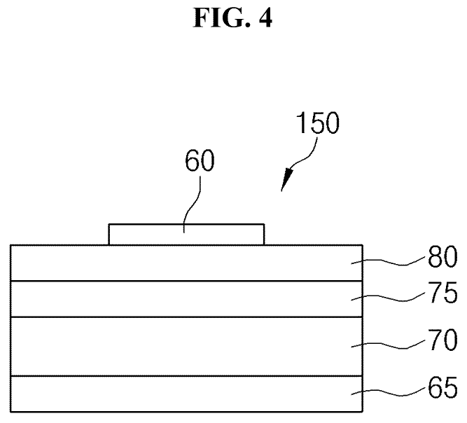

Each of the light-emitting diodes LDs can be a semiconductor light-emitting diode including a lower electrode 65 (FIG. 4), a plurality of conductive semiconductor layers 70, 75 and 80 (FIG. 4) and an upper electrode 60 (FIG. 4). As an example, the lower electrode can be a p-type electrode and the upper electrode can be an n-type electrode, but is not limited thereto.

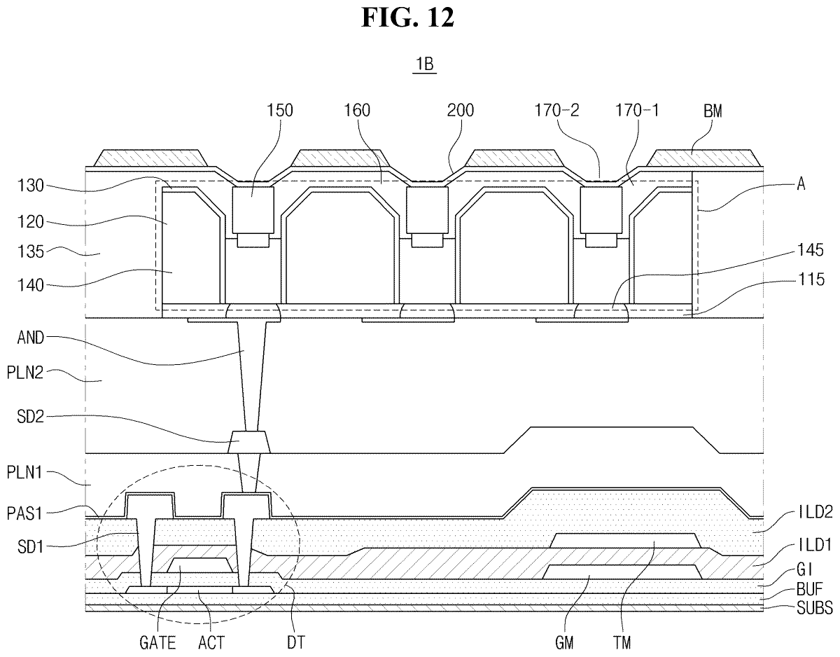

With referring to FIG. 3, the plurality of transistors can comprise a driving transistor DT supplying current to the light-emitting diodes LD, and a scan transistor ST supplying data voltage to a gate electrode GATE (FIG. 12) of the driving transistor DT. The driving transistor DT can comprise the gate electrode connected to a source electrode of the scan transistor ST, a source electrode connected to the high-potential voltage line applying the high-potential voltage, and a drain electrode connected to the lower electrode of the light-emitting diode LD. The scan transistor ST can comprise a gate electrode connected to the scan line Sk (k is an integer satisfying 1≤k≤n), a source electrode connected to the gate electrode of the driving transistor DT, and a drain electrode connected to the data line Dj (j is an integer satisfying 1≤j≤m).

The capacitor Cst can be arranged between the gate electrode and the source electrode of the driving transistor DT. The storage capacitor Cst can charge voltages corresponding to the difference between the gate voltage and the source voltage of the driving transistor DT. Each of the driving transistor DT and the scan transistor ST can be formed as a thin film transistor.

In FIG. 3, each of the first sub-pixel PX1, the second sub-pixel PX2 and the third sub-pixel PX3 comprises one driving transistor DT, one scan transistor ST and one capacitor Cst to form a 2 TIC (2 transistors and 1 capacitor), but is not limited thereto. Alternatively, each of the first sub-pixel PX1, the second sub-pixel PX2 and the third sub-pixel PX3 can comprise a plurality of the scan transistors STs and a plurality of the capacitors Csts.

With referring to FIG. 2, the driving circuit 20 output signals and voltages for driving the display panel 10. The driving circuit 20 can comprise the data driver 21 and the timing controller 22.

The data driver 21 receives digital video data DATA and source control signal CDS from the timing controller 22. The data driver 21 convert the digital video data DATA to analog data voltages by the source control signal DCS and supplies the analog data voltages to the data lines D1 to Dm of the display panel 10.

The timing controller 22 receives the digital video data DATA and timing signals form a host system. The timing signals can comprise vertical sync signal, horizontal sync signal, data enable signal and a dot clock. The host system can comprise, but is not limited to, an application processor of a mobile phone or a tablet PC, a monitor, TV system on chip.

The scan driver 30 receives a scan control signal SCS from the timing controller 22. The scan driver 30 generates a scan signal by the scan control signal SCS and supplies the scan signal to the scan lines S1 to Sn of the display panel 10. The scan driver 30 can comprise a plurality of transistors and can be arranged in the non-display area NDA of the display panel 10. Alternatively, the scan driver 30 can be formed as an integrated circuit. In this case, the scan driver 30 can be mounted on a gage flexible film attached on other side of the display panel 10.

The power supply circuit 50 can generate the high-potential voltage VDD and the low-potential voltage VSS form a main power supply for driving the light-emitting diodes LDs of the display panel 10 and supply the voltages to the high-potential voltage line and the low-potential voltage line of the display panel 10, respectively. In addition, the power supply circuit 50 can generate driving voltages for the driving circuit 20 and the scan driver 30 from the main power.

In the present disclosure, a micro light-emitting diode (micro LED) chip 150 (FIG. 4) can be exemplified as the semiconductor light-emitting diode covering current to light. The micro light-emitting diode chip 150 can be a light-emitting diode with a size or a dimension equal to or less than 100 micrometer. As high-resolution display models have been developed, the size of the light-emitting diode is reduced to the extreme, and it may be necessary to perform a task of transferring micro LED chip 150 of about 10 um or less in size with a precision of about 1 um or less. The micro LED chip 150 may be provided with blue, red and green emission areas, respectively, and a unit pixel may be implemented by that combination. In other words, the unit pixel means a minimum unit for implementing one color, and at least two (a plurality of) micro LED chips 150 can be provided in the unit pixel. As an example, the micro LED chip 150 can have a vertical structure as illustrated in FIG. 4.

For example, the micro LED chip 150 can be mainly made of gallium nitride (GaN) together adding indium (In) and/or aluminum (Al) so that the micro LED chip 150 can be implemented as a high-output light-emitting diode that emits various types of light including blue color light.

Such a vertical-type semiconductor light-emitting diode 150 can comprise a lower electrode, for example a p-type electrode 65, a p-type semiconductor layer 70 disposed on the p-type electrode 65, an active layer 75 disposed on the p-type semiconductor layer 70, an n-type semiconductor layer 80 disposed on the active layer 75 and an upper electrode, for example an n-type electrode 60 disposed on the n-type semiconductor layer 80. In this case, the p-type electrode 60 disposed at the bottom can be electrically connected to the n-type electrode 60 at the upper surface of the semiconductor light-emitting diode 150. The vertical-type micro LED chip 150 has a great advantage of reducing the chis size because the electrodes can be placed upward and downward.

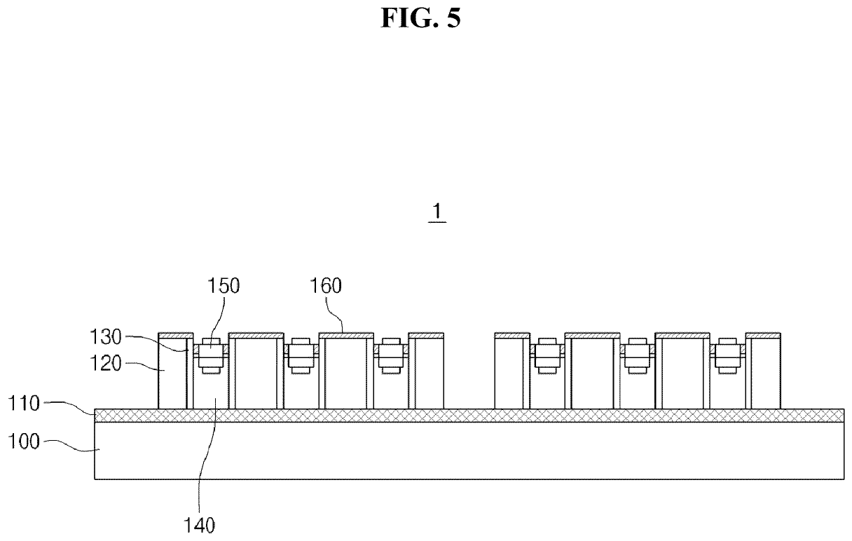

FIG. 5 illustrates a light-emitting component deposited on a base substrate in accordance with an embodiment of the present disclosure.

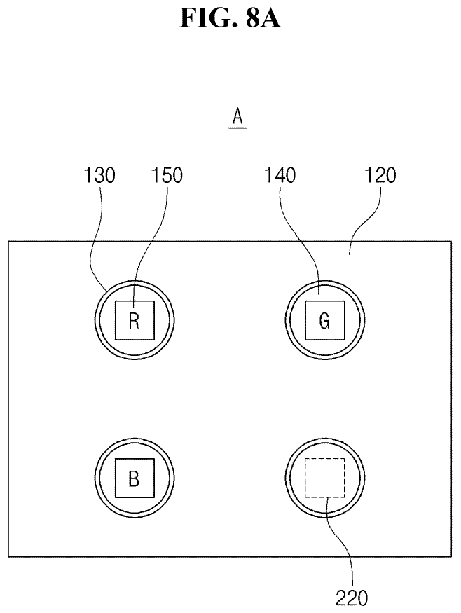

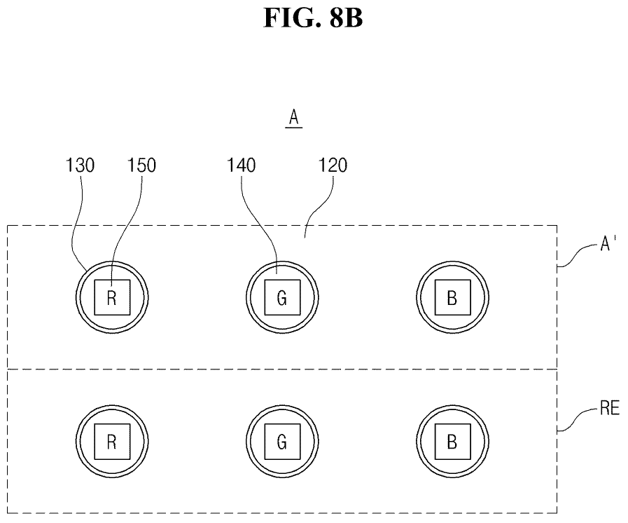

A base substrate 110 on which a light-emitting component A (FIG. 8) in accordance with an embodiment of the present disclosure can comprise, but is not limited to, glass, sapphire, silicon carbide (Sic), gallium nitride (GaN) and/or zinc oxide (ZnO).

An adhesive layer 110 can be disposed on the entire base substrate 100. The adhesive layer 110 can comprise, but is not limited to, an epoxy-containing resin, a polyimide-containing resin, a silicone-containing resin, an acryl-containing resin, a polyurethane-containing resin, and the like.

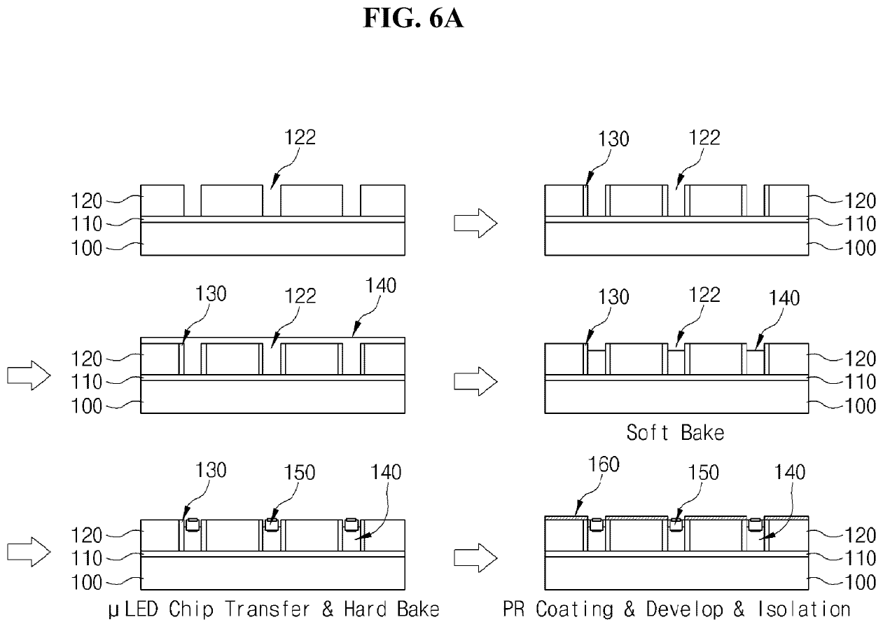

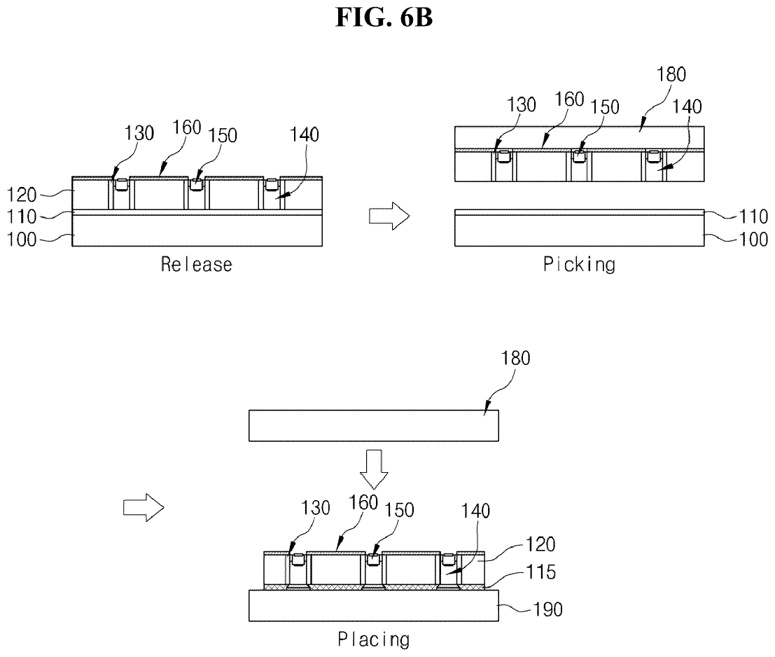

A plurality of molds 120 can be disposed or positioned on the adhesive layer 110. A plurality of recess 122 (FIG. 6) can be arranged at regular intervals between two of the molds 120. In an embodiment, the mold 120 can comprise, but is not limited to, glass material.

A reflection wall 130 can be placed on at least one outer side of each of the molds 120. For example, the reflection wall 130 can be placed on the outer side of the mold 120 facing to adjacently placed mold 120 so that the recess 122 can two reflection walls 130 at both sides. The reflection wall 130 can be disposed by depositing light-reflecting material on the outer side of the mold 120 or by adding any component with light-reflecting function. For example, the reflection wall 130 can comprise, but is not limited to, aluminum (Al), silver (Ag), platinum (Pt), gold (Au), titanium (Ti), silicon oxide (SiOx, wherein 0<x≤2), silicon nitride (SiNx, wherein 0<x≤2). The reflection wall 130 can have a single-layer structure or a multi-layer structure. The reflection wall 130 can improve the light extraction efficiency emitted from the micro LED chip 150, and thus, enables the high-dimension display apparatus to be fabricated.

A conductive layer 140 can be placed within the recess 122 of the mold 120 onto which the reflection wall 130 is disposed. The conductive layer 140 can comprise, but is not limited to, metal material or a conducive adhesive material, and therefore, the electrode of the panel can be electrically connected to the electrode of the micro LED chip 150.

In another embodiment, the display apparatus 100 can further comprise a photoresist layer 160 surrounding the sides of the micro LED chip 150 and covering the upper surface of the mold 120. After arranging or positioning the components of the mold 120, the reflective wall 130, the conductive layer 140 and the micro LED chip 150, the photoresist layer 160 is deposited. Therefore, the photoresist layer 160 can enhance the fixing forces of those components and implement flat surface structure of the light-emitting component A. In one embodiment, the photoresist layer 160 can be positioned to expose the upper surface of the micro LED chip 150 so that the electrode of the micro LED chip 150 can be electrically connected to the electrode of the panel, which will be described in more detail later.

FIGS. 6A and 6B illustrate a fabrication process of a display apparatus in accordance with an embodiment of the present disclosure.

As illustrated in the upper left panel in FIG. 6A, the adhesive layer 110 can be disposed on the entire base substrate 100. The molds 120 including the recesses 122 at a regular space therebetween can be positioned on the adhesive layer 110. As illustrated in the upper right panel in FIG. 6A, the reflection wall 130 including the light-reflecting material can be disposed in the recess 122 so that the emission efficiency of the light generated at the micro LED chip 150. As illustrated in the middle left panel in FIG. 6A, the conductive layer 140 including the conducting material can cover the molds 120 including the reflection wall 130 and the recesses 122 after disposing the reflection wall 130. As illustrated in the middle right panel in FIG. 6A, the conducive layer 140 can be reduced in volume through a soft baking or low-temperature pre-drying and can be positioned within the recess 122 disposed between two of the molds 120.

The conductive layer 140 that has passed the low-temperature pre-drying is not completely cured, so the conductive layer 140 remains flexible, but is formed in a state in which the viscosity is somewhat increased. Accordingly, as illustrated in the lower left panel in FIG. 6A, the micro LED chip 150 can be placed on the conductive layer 140 that is maintained in the elastic state. As described with referring to FIG. 4, since the micro LED chip 150 is placed as the vertical-type chip on the display panel, the lower electrode 65 of the micro LED chip 150 can be electrically connected to the conductive layer 140. After the micro LED chip 150 is transferred on the conductive layer 140, the conductive layer 140 can be hard baking to be completely cured state. The completely cured conductive layer 140 becomes a solid state with increased strength and hardness and a tightly bonded structure. Accordingly, the conductive layer 140 becomes physically and chemically stable, thereby increasing resistance to thermal, contamination, and other deformations, and can improve the transfer efficiency of the micro LED chip 150 and prevent effects such as detachment and twisting. In an embodiment, the height of the mold 120 can be equal to or higher than the height of the micro LED chip 150. Accordingly, the area in which the reflection wall 130 arranged in the recess 122 arranged between the molds 120 can reflect light is secured wider, so that maximum luminous efficiency increase can be expected.

Then, as illustrated in the lower right panel in FIG. 6A, the photoresist layer 160 can be deposited on the molds 120. The photoresist layer 160 can encloses the sides of the micro LED chip 150 and can be placed on each mold 120. In one embodiment, the photoresist layer 160 can have a negative photoresist in which an unlit portion can be removed. The portion of the photoresist layer 160 located on the upper surface of the micro LED chip 150 can be removed. In this case, the upper electrode 60 (FIG. 4) of the micro LED chip 150 is exposed so that the upper electrode 60 can be electrically connected to the panel electrode. Due to the deposition of the photoresist layer 160, the light-emitting portion A can maintain flatness and improve the fixing force among components even after the transfer the micro LED chip 150 on the conductive layer 140.

The photoresist layer 160 can be placed on the micro LED chip 150 by coating a photoresist-forming composition on the mold 120 and the micro LED chip 150, and performing a photolithography process PR process, for example, soft baking, selective exposure to the area corresponding to the mold 120 using UV light, develop and hard baking. Accordingly, finally packaged micro LED chip 150 can be fabricated.

As illustrated in FIG. 6B, the packaged micro LED chip 150 together with the molds 120, the conductive layer 140 and the photoresist layer 160 can be transferred from the base substrate 100 to the panel 190 through ‘release-picking-placing’ processes. As an example, the packaged micro LED chip 150 can be released or separated from the base substrate 100 and the adhesive layer 110 using a stamp 180, and the released packaged micro LED chip 150 can be transferred onto the panel 190. Compared to the process of transferring micro LED chip individually, the number of transfer can be reduced in the transfer process that is performed as a packaging unit including two or more micro LED chips 150. Accordingly, it is possible to reduce process defects and facilitate transfer of ultra-small micro LED chip 150 when manufacturing a large area display device.

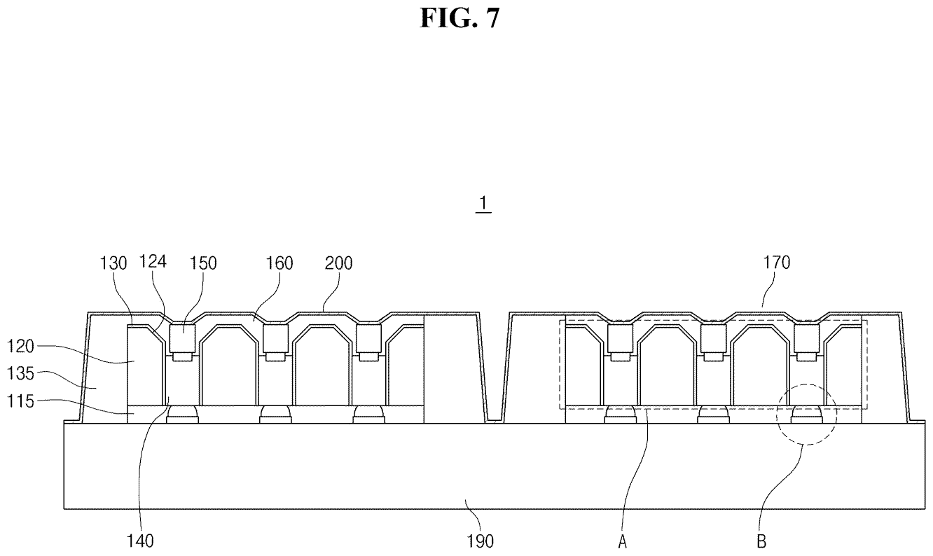

FIG. 7 illustrates a cross-sectional view of a display apparatus in accordance with an embodiment of the present disclosure. With referring to FIG. 7, the light-emitting component A and additional components disposed on the panel 190 will be described in detail.

As illustrated in FIG. 7, each of the molds 120 can include the inclined surface 124 to diffuse light emitted from the micro LED chip 150. In one embodiment, the molds 120 can comprise glass material. In this case, the reflection wall 130 can be deposited using metal and an oxidation layer of oxide-containing material can be disposed on the reflection wall 130 to insulate the reflection wall 130. Accordingly, it is possible to prevent poor connection between the micro LED chip 150 and the panel circuit while enabling reflection light emitted from the micro LED chip 150.

Alternatively, when the mold 120 comprises a silicon-containing material, it is possible to reflect light emitted from the micro LED chip 150 without the additional reflection wall 130. In this case, the mold 120 of the silicon-containing material can be oxidized to form an oxidation layer of silicon oxide (SiOx, wherein 0<x≤2) such as SiO₂ which can be function as an insulator, and therefore, it is possible to prevent a poor connection between the micro LED chip 150 and the panel circuit. However, the material for the mold 120 is not limited thereto.

A second electrode 200 can be positioned or disposed on the micro LED chip 150 exposed by the photoresist layer 160. In some embodiments, since the micro LED chip 150 applying the vertical-type chip includes electrodes 60 and 65 (FIG. 4) at the upper surface and the lower surface thereof, the upper electrode 60 of the micro LED chip 150 can be electrically connected to the second electrode 200.

The packaged micro LED chip 150 structure including the second electrode 200 can be referred to the light-emitting component A. The panel 190 can include an insulating layer 130 disposed on thereof. The insulating layer 130 can comprise a plurality of holes 170 formed on thereof. The light-emitting component A can be placed within the hole 170 of the insulating layer 135. Each of the molds 120 can be disposed between the micro LED chips 150 to prevent mixing of light, and the luminous efficiency of the micro LED chip 150 can be maximized by disposing the inclination surface 124 and/or the reflection wall 130 on the sides of the mold 120.

FIGS. 8A and 8B illustrate a plane view of an area A as a light-emitting component in FIG. 7 in accordance with an embodiment of the present disclosure.

As illustrated in FIG. 8A, the light-emitting component A can comprise red (R), green (G) and blue (B) micro LED chips 150, and optionally, a repair portion 220. Alternatively, as illustrated in FIG. 8B, the light-emitting component A can comprise a main light-emitting portion A′ and a redundancy portion RE. The red (R), the green (G) and blue (B) micro LED chip 150 can be mounted in the main light-emitting portion A′ and the redundancy portion RE, respectively. The micro LED chip 150 arranged in the main light-emitting portion A′ can be a main or primary light-emitting diode, and the micro LED chip 150 arranged in the redundancy portion RE can be a spare light-emitting diode transferred in preparation for a failure of the main light-emitting portion A′. In case of a failure of the main light-emitting portion A′, the redundancy portion RE can be used as a replacement. The main light-emitting portion A′ and the redundancy portion RE in one pixel are transferred together to the panel 190 so that it is possible to minimize the image quality reduction due to the failure of the main light-emitting component A′. The repair portion 220 in FIG. 8A can be used as a replacement for individual failure of the micro LED chip 150 similar to the redundancy portion RE in FIG. 8B.

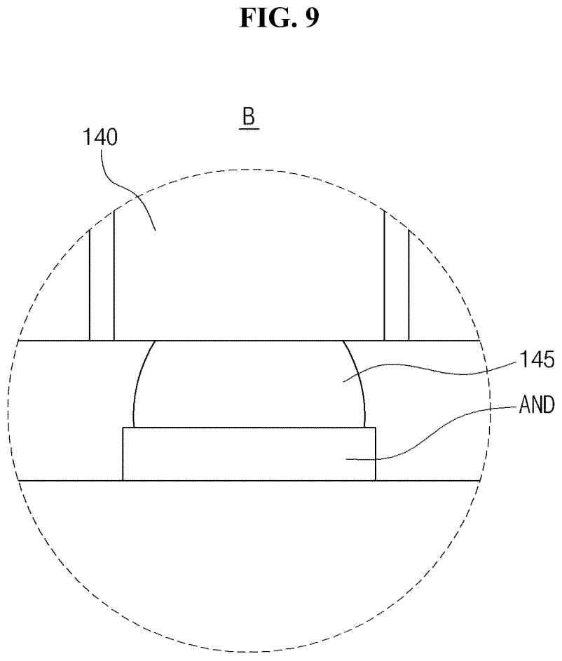

FIG. 9 illustrates an enlarged cross-sectional view of an area B in FIG. 7.

As illustrated in FIGS. 7 and 9, an adhesive member 145 can be disposed under the conductive layer 140 arranged under the micro LED chip 150. In one embodiment, the adhesive member 140 can comprise a conductive adhesive material. For example, the adhesive member 145 can comprise, but is not limited to, an epoxy-containing, a silver paste-containing and/or a carbon-containing conductive adhesive material. The first electrode AND (FIG. 12) of the panel 190 can be electrically connected to the lower electrode 65 (FIG. 4) of the micro LED chip 150 through the conductive adhesive member 145.

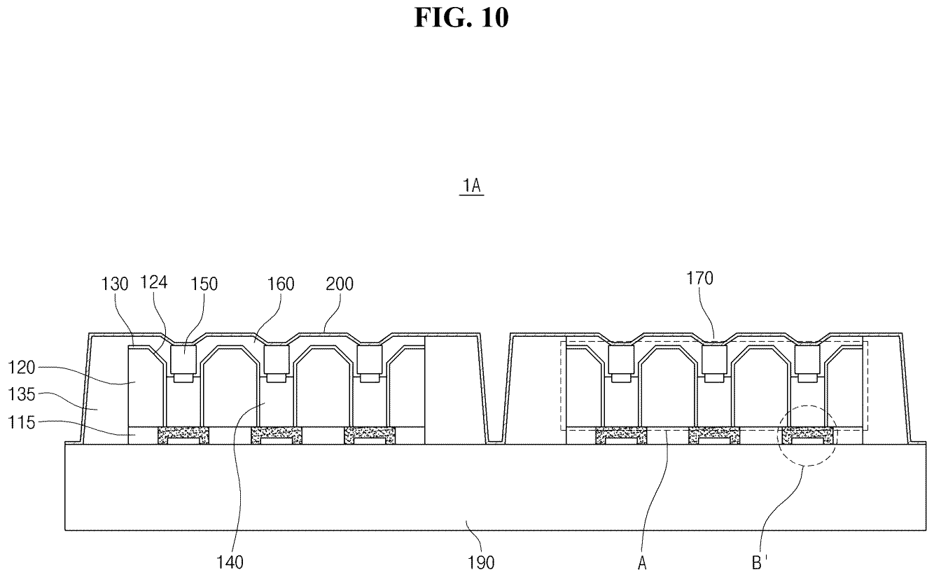

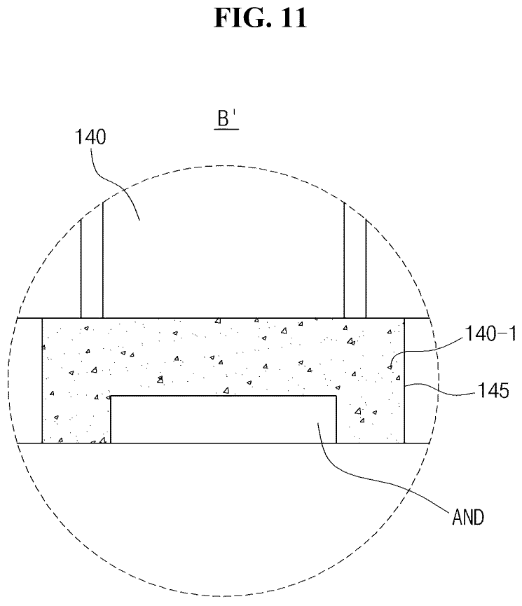

FIG. 10 illustrates a cross-sectional view of a display apparatus in accordance with another embodiment of the present disclosure. FIG. 11 illustrates an enlarged cross-sectional view of an area B′ in FIG. 10.

With referring FIGS. 10 and 11, the adhesive member 145 can comprise a conductive ball 140-1 in the display apparatus 1A in accordance with another embodiment. As an example, the adhesive member 145 can be an Anisotropic Conductive Film (ACF) though which the light-emitting component A can be electrically connected to the first anode AND (FIG. 12) of the panel 190. When the micro LED chip 150 is individually transferred, it may be difficult to form the adhesive member 145 of a size of 10 um or less. However, In case of the micro LED chip 150 structure packaged with the light-emitting component A in some embodiments, it may be easier to use the adhesive member 145. The adhesive member 145 can be formed only at the connection location of the electrodes, thereby, enabling individual driving and inspection of the micro LED chip 150.

FIG. 12 illustrates a cross-sectional view of a display apparatus in accordance with an embodiment of the present disclosure. Although not shown in FIG. 12, the substrate SUBS of the display apparatus 1B may comprise multiple pieces that include an interlayer insulating layer therebetween, which can prevent moisture penetration. For example, a plurality of substrates SBUBs can be a polyimide (PI) substrate, respectively. Alternatively, the substrate SUBS can comprise, but is not limited to, a glass material.

A buffer layer BUF can be disposed on the substrate SUBS. The buffer layer BUF can comprise multiple buffer layers.

An active layer ACT of the driving transistor DT can be disposed on the buffer layer BUF. A gate insulating layer GI can be disposed on the active layer ACT to cover the active layer ACT.

The gate electrode GATE of the driving transistor DT can be disposed on the gate insulating layer GI. A gate material layer GM can be disposed on the gate insulating layer GI together with the gate electrode GATE of the driving transistor DT in other location of the driving transistor DT.

A first interlayer insulating layer ILD1 can be disposed covering the gate electrode GATE and the gate material layer GM. A metal pattern TM can be disposed on the first interlayer insulating layer ILD1. A second interlayer insulating layer ILD2 can be disposed on the metal pattern TM covering the metal pattern TM.

Two first source-drain electrode patterns SD1 can be disposed on the second interlayer insulating layer ILD2. One of the first source-drain electrode patterns SD1 can be a source node of the driving transistor DT, and the other of the first source-drain electrode patterns SD1 can be a drain node of the driving transistor DT.

Each of the first source-drain electrode patterns SD1 can be connected to one side and the other side of the active layer ACT through contact holes formed in the first interlayer insulating layer ILD1 and the gate insulating layer GI, respectively. An area where the active layer ACT is overlapped with the gate electrode GATE can be a channel area. One of the first source-drain electrode patterns SD1 can be connected to one side of the channel area in the active layer ACT, and the other of the first source-drain electrode patterns SD1 can be connected to the other side of the channel area in the active layer ACT.

A first planarization layer PLN1 and a second planarization layer PLN2 can be disposed on the first source-drain electrode patterns SD1.

The first planarization layer PLN1 can be disposed on the first source-drain electrode patterns SD1. A second source-drain electrode pattern SD2 can be disposed on the first planarization layer PLN1. The second source-drain electrode pattern SD2 can be connected to one of the source-drain electrode patterns SD1 through a contact hole formed in the first planarization layer PLN1.

The second planarization layer PLN2 can be disposed on the second source-drain electrode patterns SD2 covering the second source-drain electrode pattern SD2.

The first electrode AND can be disposed on the second planarization layer PLN2. The first electrode AND can be electrically connected to the second source-drain electrode pattern SD2 through a contact hole formed in the second planarization layer PLN2. The first electrode AND can be contacted to the adhesive member 145 and can be electrically connected to the lower electrode 65 (FIG. 4) of the micro LED chip 150.

In one embodiment, a filling material 115 can be disposed between the second planarization layer PLN2 on which the first electrode AND is disposed and the light-emitting component A. The filling material 115 enables the adhesive member 145 to be fixed firmly and the light-emitting component A to be disposed uniformly with beneficial transfer flatness.

As described above, the light-emitting component A can be disposed within the hole 170 of the insulating layer 135 positioned on the panel 190 (FIGS. 7 and 10). The insulating layer 135 can prevent the poor connection between the light-emitting component A of a pixel unit and the panel circuit. In addition, the insulating layer 135 can direct light emitted from the micro LED chip 150 in a specific direction and convert a point light source into a surface light source.

The second electrode 200 can be connected to the upper electrode 60 (FIG. 4) of the micro LED chip 150 of which the upper surface is exposed by the photoresist layer 160. Accordingly, the panel circuit can be electrically connected to the light-emitting component A. In one embodiment, a black matrix BM can be disposed on the second electrode 200. The black matrix BM can be arranged in an area other than the upper surface of the micro LED chip 150. The black matrix BM can reduce the mixing of light and external light reflection among the plural sub-pixels PX1, PX2 and PX3 (FIG. 2).

In some embodiments, the black matrix BM can comprise, but is not limited to, non-transparent material. For example, the black matrix BM can comprise, but is not limited to, an organic insulating material such as a black dye and/or a black pigment.

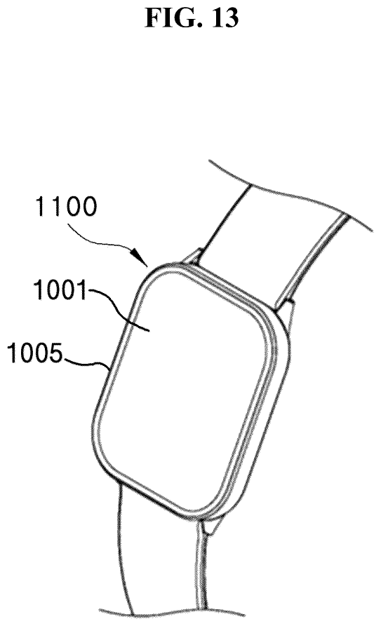

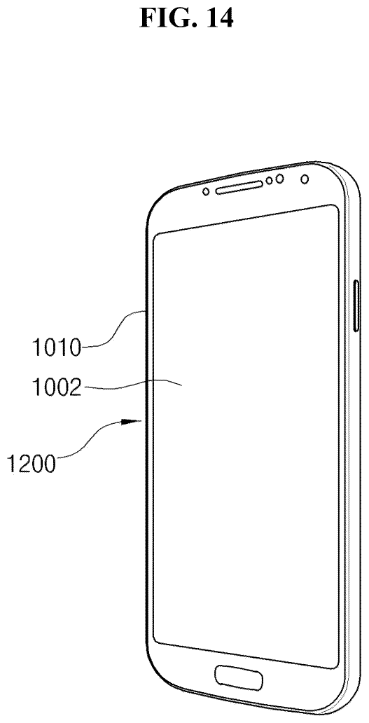

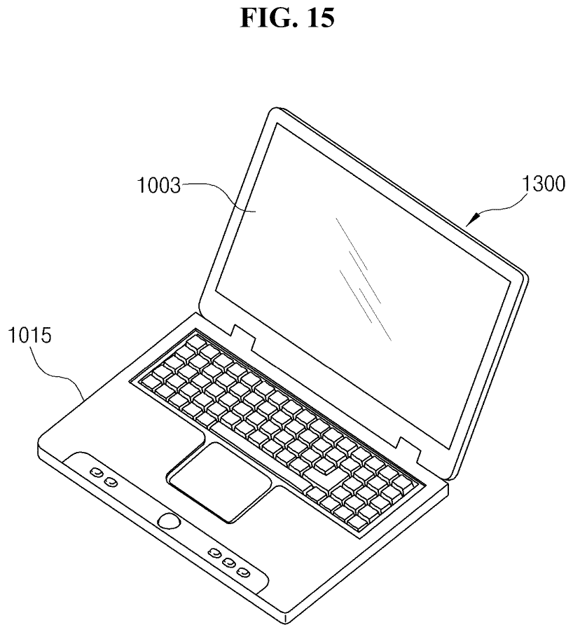

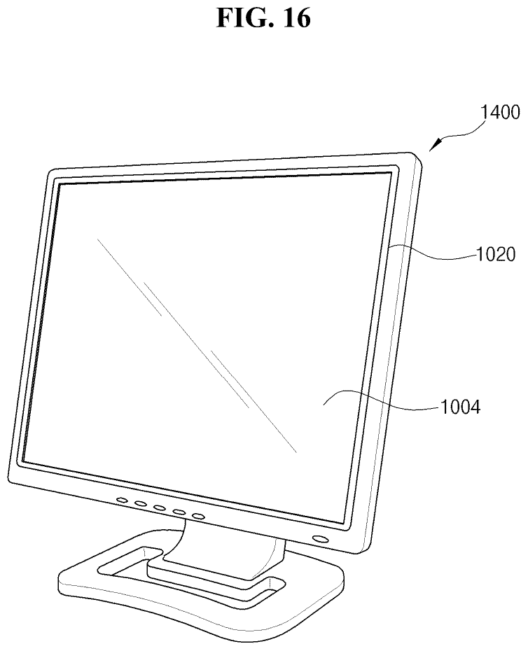

FIGS. 13 to 16 illustrate devices including the display apparatus in accordance with embodiments of the present disclosure.

With referring to FIGS. 13 to 16, the display apparatus 1, 1A or 1B (FIGS. 7, 10 and 12) in accordance with embodiments can be applied to various devices and/or electronic devices. For example, as illustrated in FIGS. 13 to 16, the electronic devices can comprise, but is not limited to, a wearable device 1100, a mobile device 1200, a notebook 1300 and a monitor or a television 1400.

In one embodiments, each of the wearable device 1100, the mobile device 1200, the notebook 1300 and the monitor or television 1400 can comprise a case portion 1005, 1010, 1015 or 1020, and the display panel 10 and/or the display apparatus 1, 1A or 1B as described with referring to FIGS. 1 to 12.

For example, the display apparatuses 1, 1A and/or 1B in embodiments of the present disclosure can be applied to a mobile device, a video phone, a smart watch, a watch phone, wearable devices, a foldable apparatus, a rollable apparatus, a bendable apparatus, a flexible apparatus, a curve apparatus, a sliding apparatus, a variable apparatus, an electronic notebook, an electronic book, a portable multimedia player (PMP), a personal digital assistant (PDA), an MP3 player, a mobile medical apparatus, a desktop PC, a laptop PC, a netbook computer, a workstation, a navigation apparatus, a display apparatus for a vehicle, a display apparatus for a theater, a television, a wallpaper apparatus, a signage apparatus, a game device, a notebook, a monitor, a camera, a camcorder, home appliances, and the like.

The description herein has been presented to enable any person skilled in the art to make, use and practice the technical features of the present disclosure, and has been provided in the context of one or more particular example applications and their example requirements. Various modifications, additions and substitutions to the described embodiments will be readily apparent to those skilled in the art, and the principles described herein may be applied to other embodiments and applications without departing from the scope of the present disclosure. The description herein and the accompanying drawings provide examples of the technical features of the present disclosure for illustrative purposes. In other words, the disclosed embodiments are intended to illustrate the scope of the technical features of the present disclosure. Thus, the scope of the present disclosure is not limited to the embodiments shown, but is to be accorded the widest scope consistent with the claims. The scope of protection of the present disclosure should be construed based on the following claims, and all technical features within the scope of equivalents thereof should be construed as being included within the scope of the present disclosure.

1. A display apparatus, comprising:
a substrate;
a first electrode disposed on the substrate;
a thin film transistor disposed on the substrate and electrically connected to the first electrode;
a planarization layer disposed on the thin film transistor;
an insulating layer disposed on the planarization and comprising a plurality of holes; and
a light-emitting component disposed within the plurality of holes.

2. The display apparatus of claim 1, wherein the light-emitting component comprises:
a plurality of micro light-emitting diode chips;
a plurality of molds surrounding each of the plurality of micro light-emitting diode chips, respectively;
a reflection wall positioned on at least one outer side of each of the plurality of molds;
a conductive layer disposed under each of the plurality of micro light-emitting diode chips; and
a second electrode disposed on the plurality of micro light-emitting diode chips,
wherein the plurality of micro light-emitting diode chips are electrically connected to the conductive layer and the second electrode.

3. The display apparatus of claim 2, wherein the display apparatus further comprises a photoresist layer surrounding sides of the plurality of micro light-emitting diode chips, and wherein the photoresist layer is positioned to expose an upper end of the plurality of micro light-emitting diode chips.

4. The display apparatus of claim 2, wherein each of the plurality of molds comprises an inclined surface configured to diffuse light generated from each of the plurality of micro light-emitting diode chips.

5. The display apparatus of claim 2, wherein each of the plurality of molds has a height equal to or higher than a height of each of the plurality of micro light-emitting diode chips.

6. The display apparatus of claim 2, wherein each of the plurality of micro light-emitting diode chips is a vertical chip.

7. The display apparatus of claim 2, wherein the light-emitting component further comprises a repair portion.

8. The display apparatus of claim 2, wherein the light-emitting component further comprises a redundancy portion.

9. The display apparatus of claim 1, wherein the display apparatus further comprises an adhesive member positioned under the light-emitting component, and wherein the light-emitting component is electrically connected to the first electrode through the adhesive member.

10. The display apparatus of claim 9, wherein the adhesive member comprises a conductive material.

11. The display apparatus of claim 7, wherein the adhesive member comprises a conductive ball.

12. The display apparatus of claim 1, wherein the display apparatus further comprises a filling material between the light-emitting component and the planarization layer.

13. The display apparatus of claim 1, wherein the display apparatus further comprises a black matrix disposed on the second electrode, and wherein the black matrix is positioned to expose an upper end of the plurality of micro light-emitting diode chips.

14. A process of fabricating a display apparatus, the process comprising:
preparing a base substrate;
disposing an adhesive layer on the entire base substrate;
disposing a plurality of molds on the adhesive layer so that recesses are positioned between two of the plurality of the molds;
disposing a reflective wall surrounding an outer wall of each of the plurality of the molds;
treating thermally the conductive layer to position the conductive layer within each of the recess between two of the plurality of the molds;
transferring a plurality of micro light-emitting diode chips on the conductive layer; and
curing the conductive layer.

15. The process of claim 14, the process further comprising disposing a photoresist layer on the plurality of the micro light-emitting diode chips.

16. The process of claim 15, wherein disposing the photoresist layer comprises coating a photoresist-forming composition on the plurality of the micro light-emitting diode chips and performing a photolithography process for the photoresist-forming composition.

17. The process of claim 15, wherein the process further comprising isolating the plurality of the micro light-emitting diode chips transferred on the conductive layer from the adhesive layer using a stamp, and arranging the plurality of the micro light-emitting diode chips transferred to the conductive layer onto a panel.

18. The process of claim 17, wherein an insulating layer including a plurality of holes is disposed on the panel, and wherein the plurality of the micro light-emitting diode chips transferred on the conductive layer are positioned within the plurality of holes.

19. The process of claim 15, wherein the process further comprising depositing a second electrode on the entire photoresist layer.

20. The process of claim 18, wherein the process further comprising disposing a black matrix on the second electrode.
